(19) United States
(12) Patent Application Publication
(10) Pub. No.: US 2026/0155193 A1
(43) Pub. Date: Jun. 4, 2026

(54) SYSTEM AND METHOD FOR WORDLINE GROUP-BASED MACHINE LEARNING MODELS

(71) Applicant: Microchip Technology Incorporated, Chandler, AZ (US)

(72) Inventors: Michele Cirella, Castelmassa (IT); Pitamber Shukla, San Jose, CA (US); Salvatrice Scommegna, Cornate D'Adda (IT); Antonio Aldarese, Vimercate (IT)

(73) Assignee: Microchip Technology Incorporated, Chandler, AZ (US)

(21) Appl. No.: 19/176,444

(22) Filed: Apr. 11, 2025

Related U.S. Application Data
(60) Provisional application No. 63/728,039, filed on Dec. 4, 2024.

(51) Int. Cl. G11C 29/12

(52) U.S. Cl. CPC G11C 29/12005; G11C 2029/1202

(57) ABSTRACT

A data storage system includes a memory device (e.g., a solid state drive) including a wordline (WL), a memory (e.g., a random access memory) including instructions stored thereon, and at least one processor. The memory includes instructions stored thereon that, when executed by the at least one processor, cause the at least one processor to: select a machine learning (ML) model based at least in part on error values for the WL; determine, by the ML model, a read voltage threshold; and read data from the WL using the read voltage threshold.

### CROSS-REFERENCE TO RELATED APPLICATIONS

The current patent application claims the benefit under 35 U.S.C. § 119(e) of the priority date of U.S. Provisional Application Ser. No. 63/728,039; titled “WORDLINE GROUP-BASED MACHINE LEARNING MODELS TO IMPROVE ACCURACY OF BEST VT PREDICTION”; and filed December 4, 2024. The Provisional Application is hereby incorporated by reference, in its entirety, into the current patent application.

### TECHNICAL FIELD

Various examples of the present disclosure relate to systems and methods for wordline (WL) group-based machine learning to determine a read voltage threshold.

### BACKGROUND

Memory devices typically perform read operations using reference voltages corresponding to read voltage thresholds. The read voltage threshold may be a default, static read voltage threshold or may be a dynamic read voltage threshold. In the case of a dynamic read voltage threshold, algorithms such as background read positioning (BRP) and/or read retry (RR) may be utilized to determine a read voltage threshold that may reduce or minimize a number of read errors produced during read operations. These algorithms may utilize significant resources (e.g., time) to determine the read voltage threshold due to the number of read operations necessary to converge on the optimized read voltage threshold.

This background discussion is intended to provide information related to the present invention which is not necessarily prior art.

### SUMMARY OF THE INVENTION

According to various examples of the present disclosure, a data storage system includes a memory device including a wordline (WL), a memory, and at least one processor. The memory includes instructions stored thereon that, when executed by the at least one processor, cause the at least one processor to: select a machine learning (ML) model based at least in part on error values for the WL; determine, by the ML model, a read voltage threshold; and read data from the WL using the read voltage threshold.

According to various examples of the present disclosure, a computer-implemented method includes: generating error profiles for a plurality of WLs; selecting a subset of the plurality of WLs based on the error profiles; selecting a ML model based at least in part on the error profiles of the subset; and determining, by the ML model, a read threshold voltage.

According to various examples of the present disclosure, a computer-implemented method includes: generating error profiles for a plurality of WLs; selecting a subset of the plurality of WLs based on the error profiles; and training a ML model, with the error profiles of the subset, to determine a read voltage threshold.

This summary is not intended to identify essential features of the examples, and is not intended to be used to limit the scope of the claims. These and other aspects of the present examples are described below in greater detail.

### BRIEF DESCRIPTION OF THE DRAWINGS

FIG. 1 illustrates an example system for WL group-based machine learning to determine a read voltage threshold;

FIG. 2 illustrates an example computing system configured to perform operations in accordance with the various examples of the present disclosure;

FIG. 3 illustrates an example non-volatile memory (NVM) media of the system of FIG. 1;

FIG. 4 illustrates an example physical memory block of the NVM media of FIG. 3;

FIG. 5 illustrates an example method for using a trained machine learning model to determine a read voltage threshold;

FIG. 6 illustrates another example method for using a trained machine learning model to determine a read voltage threshold;

FIG. 7 illustrates an example method for selecting error profiles of a subset of WLs for training a machine learning model; and

FIG. 8 illustrates an example method for training a machine learning model to determine a read voltage threshold.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms "exemplary," "by example," and "for example," means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Various examples of the present disclosure may be used in single-level cell (SLC) systems, multi-level cell (MLC) systems, triple-level cell (TLC) systems, quad-level cell (QLC) systems, and penta-level cell (PLC) systems, without limitation. Applications may include consumer hard drives, high performance computing (HPC), data transfer for AI, and data center solutions (DCS), without limitation.

The term “signal” or “electronic signal” may be used to describe an electromagnetic wave conducted through an electrically conductive medium in which an electric voltage and/or an electric current varies, or may be constant, over time.

In various examples of the present disclosure, a data storage system may include a memory device and a controller. The memory device may store data. The data storage system may be connected to a host system. The controller may be operable to manage storage and retrieval of data between the memory device and the host system.

The host system may send a read request to the data storage system. The read request may indicate data to be retrieved from the memory device and sent back to the host system. The controller may process the read request, retrieve the data from the memory device, process the retrieved data, and send the retrieved data to the host system. The data may be read from the memory device using a threshold voltage.

Generally, a read voltage threshold may correspond to a reference voltage used when reading data from a cell. During a read operation, a read voltage may be applied to a page, or row of cells. In response to applying the read voltage, each cell may produce a current having a voltage value corresponding to a voltage threshold of that cell. The voltage threshold of the cells may be compared to the reference voltage to determine the value of the data in the cells. In the case of a triple-level cell (TLC), seven (7) different reference voltages are needed to read the three (3) bits stored in the TLC. Specifically, two (2) reference voltages may be used to read a first bit from the TLC, three (3) reference voltages may be used to read a second bit from the TLC, and two (2) reference voltages may be used to read a third bit from the TLC.

Voltage thresholds of the cells may shift over time due to degradation and/or different operation conditions of the memory device. Accordingly, the controller may adjust the read voltage thresholds to compensate for the shifted voltage thresholds.

In various examples of the present disclosure, the controller may select a machine learning (ML) model to determine the read voltage threshold. The selection may be based on error profiles of a subset of wordlines (WLs) of the memory device. The error profiles may include error values and other information corresponding to the WLs. The error profiles of the subset may be similar (e.g., producing a similar number of errors, having undergone a similar number of program/erase (P/E) cycles, and/or the like).

The selected ML model may be trained on error profiles having similar characteristics as the error profiles of the subset of WLs. For example, training data for the ML model may include error profiles and/or error values for a set of WLs. The selected ML model may determine the read voltage threshold based on the error profiles and/or error values of the subset of WLs. More specifically, the error profiles and/or error values may be input to the ML model. The ML model may predict a number of errors produced by the subset of WLs for each of a plurality of read voltage thresholds, respectively. The determined read voltage threshold may be associated with a lower number of predicted errors than others of the read voltage thresholds, as determined by the ML model. The controller may read data from a WL using the read voltage threshold.

In various examples, the selected ML model may be one of a plurality of ML models trained to determine read voltage thresholds. Each ML model may be trained on error profiles of various different WL subsets. In various examples, the plurality of ML models may be trained by a manufacturer in an offline environment. However, it is foreseen that online training may also occur without departing from the spirit of the present disclosure.

The error profiles for the different WL subsets may, for example, be representative of errors produced by the WLs at various stages of the life cycle of the memory device. The plurality of trained ML models may be stored in the controller such that, during operation, the controller may select one of the ML models to determine a read voltage threshold based on error profiles of a subset of WLs.

Each error profile may include statistical information regarding a WL, such as a number of P/E cycles, a number of errors produced, an average temperature, an average read time, a data retention time, and/or the like, without limitation. Various subsets of the WLs may be selected to train a ML model based on any one and/or all types of statistical information included in the error profiles.

Accordingly, the utilization of ML models to determine read voltage thresholds may reduce an amount of time used to compute the read voltage thresholds compared to conventional algorithms, such as background read positioning (BRP), which requires a large number of read operations to be performed. Moreover, determining read voltage thresholds by predicting error values using error profiles for a subset of WLs may improve read voltage threshold determination accuracy over conventional algorithms, including by reducing outliers and utilizing ML models trained on different groupings of WL error profiles for different conditions.

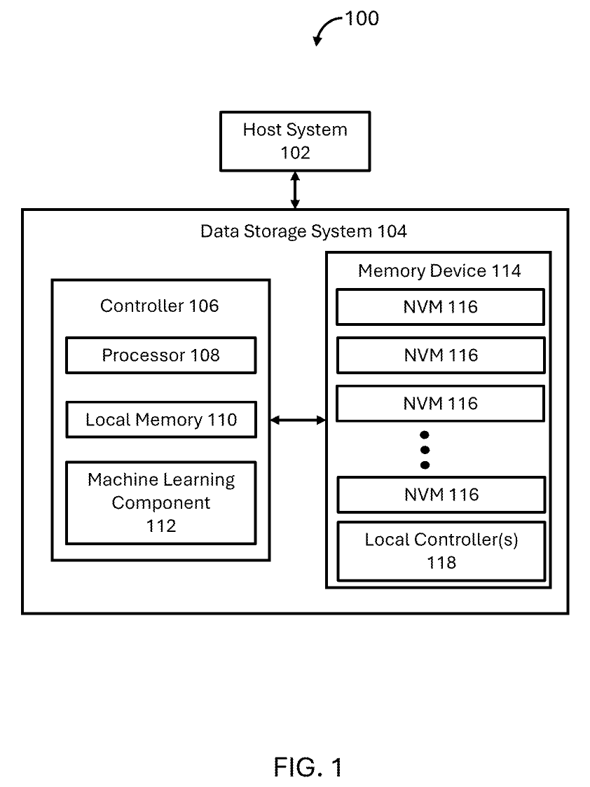

FIG. 1 illustrates an example system 100 including a host system 102 and a data storage system 104. The data storage system 104 includes include a controller 106 and a memory device 114. The controller 106 includes a processor 108, a local memory 110, and a machine learning (ML) component 112. The memory device 114 includes a plurality of non-volatile memory (NVM) media 116 and one or more local controller(s) 118. In various examples, the local controller(s) 118 may include one or more temperature sensors for measuring a temperature of the memory device 114.

In various examples, a read or write request may be received from the host system 102 via a peripheral component interconnect express (PCIe) interface that connects the data storage system 104 to servers or CPUs. PCIe is a standardized interface for motherboard components. In various examples, the data storage system may be connected to the host system by wired or wireless means (e.g., through a communications network). The data storage system may be connected to more than one host system, such as in a multi-tenant environment, without limitation.

The controller 106 may use logical block addresses (LBAs) and physical block addresses (PBAs) to facilitate access for data storage in and retrieval from the NVM media 116. LBAs are an abstraction to allow the operating system to interact with the NVM media 116, and PBAs represent the actual hardware locations within the NVM media 116. To facilitate interacting with the NVM media 116, the controller 106 may create an entry or record that assigns an LBA to a PBA. To keep track of all such LBA-to-PBA assignments, the controller 106 may use a logical-to-physical (L2P) mapping table. The L2P table may be uploaded to the local memory 110 so that it can be more quickly accessed and updated by the controller 106. In various examples, the local memory 110 may include a synchronous dynamic random access memory (SDRAM), without limitation.

When a data request is received from the host system 102, the controller 106 references the L2P mapping table to determine the PBA within the NVM media 116 corresponding to a desired LBA. Once the PBA is determined, the controller 106 accesses the appropriate NVM media 116 to write or read the data. Access to the NVM media 116 may be via a flash physical (PHY) interface. The controller 106 may employ an error correction code (ECC) operation during encoding and decoding data to detect and correct errors and enhance data integrity. Additionally, the memory device 114 may support a direct memory access (DMA) operation enabling data to be written from the host system 102 directly to the NVM media 116 and read from the NVM media 116 directly to the host system 102. Certain commands may be issued to the controller 106 or the local controller(s) 118 using the host command layer, or non-volatile memory express management interface (NVMe-MI).

In various examples, the data storage system 104 may be a solid state drive (SSD), and the NVM media 116 may be NAND-based flash memory. It would be appreciated by one of ordinary skill in the art that other memory devices (e.g., NOR flash memory, random access memory, and the like) may be utilized in the various examples described herein without departing from the spirit of the present disclosure.

In various examples, the controller 106 may receive a write request from the host system 102. The write request may include user data to be written to one or more of the NVM media 116 of the memory device 114. The user data may include, for example, media (e.g., photos, videos, and/or audio), system information data, application data, sensor data, document data, recordkeeping data, machine learning/artificial intelligence data, gaming system data, data pertaining to internal operations of the host system, and the like, without limitation.

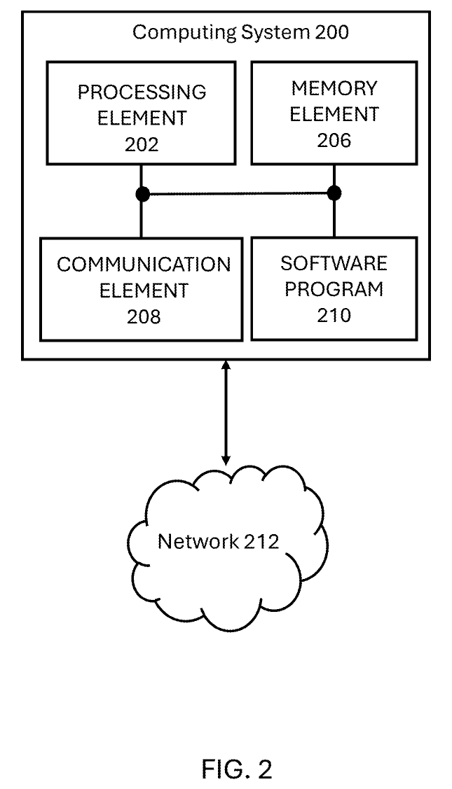

FIG. 2 illustrates a computing system 200 connected to a communication network 212. The computing system 200 may include at least one processing element 202, at least one memory element 206, a communication element 208, and a software program 210. In various examples, the computing system 200 may be a host system (e.g., the host system 102 of FIG. 1), a data storage system (e.g., the data storage system 104 of FIG. 1), and/or another computing device configured to perform some and/or all operations of the various examples of the present disclosure, without limitation.

The software program 210 may be configured with instructions for performing and/or enabling performance of at least some of the steps set forth herein. In an example, the software program 210 comprises instructions stored on computer-readable media of memory element 206. In various examples, the software program 210 may include instructions for performing operations of the ML component 112 and/or the read voltage adjustment component 113 discussed with reference to FIG. 1.

The communication network 212 generally allows communication between the computing system 200 and another computing device, such as between a remote host system (e.g., the host system 102), a local host system, and/or a data storage system (e.g., the data storage system 104 of FIG. 1), without limitation.

The communication network 212 may include the Internet, cellular communication networks, local area networks, metro area networks, wide area networks, cloud networks, plain old telephone service (POTS) networks, and the like, or combinations thereof. The communication network 212 may be wired, wireless, or combinations thereof and may include components such as modems, gateways, switches, routers, hubs, access points, repeaters, towers, and the like. The computing system 200 may, for example, connect to the communication network 212 either through wires, such as electrical cables or fiber optic cables, or wirelessly, such as RF communication using wireless standards such as cellular 2G, 3G, 4G or 5G, Institute of Electrical and Electronics Engineers (IEEE) 802.11 standards such as WiFi, IEEE 802.16 standards such as WiMAX, Bluetooth™, or combinations thereof.

The communication element 208 generally allows communication between the computing system 200 and the communication network 212. The communication element 208 may include signal or data transmitting and receiving circuits, such as antennas, amplifiers, filters, mixers, oscillators, digital signal processors (DSPs), and the like. The communication element 208 may establish communication wirelessly by utilizing radio frequency (RF) signals and/or data that comply with communication standards such as cellular 2G, 3G, 4G or 5G, Institute of Electrical and Electronics Engineers (IEEE) 802.11 standard, such as WiFi, IEEE 802.16 standard, such as WiMAX, Bluetooth™, or combinations thereof. In addition, the communication element 208 may utilize communication standards such as ANT, ANT+, Bluetooth™ low energy (BLE), the industrial, scientific, and medical (ISM) band at 2.4 gigahertz (GHz), or the like. Alternatively, or in addition, the communication element 208 may establish communication through connectors or couplers that receive metal conductor wires or cables, like Cat 6 or coax cable, which are compatible with networking technologies such as ethernet. In certain examples, the communication element 208 may also couple with optical fiber cables. The communication element 208 may respectively be in communication with the processing element 202 and/or the memory element 206.

The memory element 206 may include electronic hardware data storage components such as read-only memory (ROM), programmable ROM, erasable programmable ROM, random-access memory (RAM) such as static RAM (SRAM) or dynamic RAM (DRAM), solid state drives (SSDs), cache memory, hard disks, floppy disks, optical disks, flash memory, thumb drives, universal serial bus (USB) drives, or the like, or combinations thereof. In some examples, the memory element 206 may be embedded in, or packaged in the same package as, the processing element 202. The memory element 206 may include, or may constitute, a “computer-readable medium.” The memory element 206 may store the instructions, code, code segments, software, firmware, programs, applications, apps, services, daemons, or the like that are executed by the processing element 202. In various examples, the memory element 206 respectively store the software applications/program 210. The memory element 206 may also store settings, data, documents, sound files, photographs, movies, images, databases, and the like. In various examples, the memory element 206 may include a first memory component (e.g., the local memory 110 of FIG. 1) and one or more SSDs (e.g., the memory device 114 of FIG. 1).

The processing element 202 may include electronic hardware components such as processors. The processing element 202 may include digital processing unit(s). The processing element 202 may include microprocessors (single-core and multi-core), microcontrollers, digital signal processors (DSPs), field-programmable gate arrays (FPGAs), analog and/or digital application-specific integrated circuits (ASICs), or the like, or combinations thereof. The processing element 202 may generally execute, process, or run instructions, code, code segments, software, firmware, programs, applications, apps, processes, services, daemons, or the like. For instance, the processing element 202 may respectively execute the software applications/program 210. The processing element 202 may also include hardware components such as finite-state machines, sequential and combinational logic, and other electronic circuits that can perform the functions necessary for the operation of the current disclosure. The processing element 202 may be in communication with the other electronic components through serial or parallel links that include universal busses, address busses, data busses, control lines, and the like.

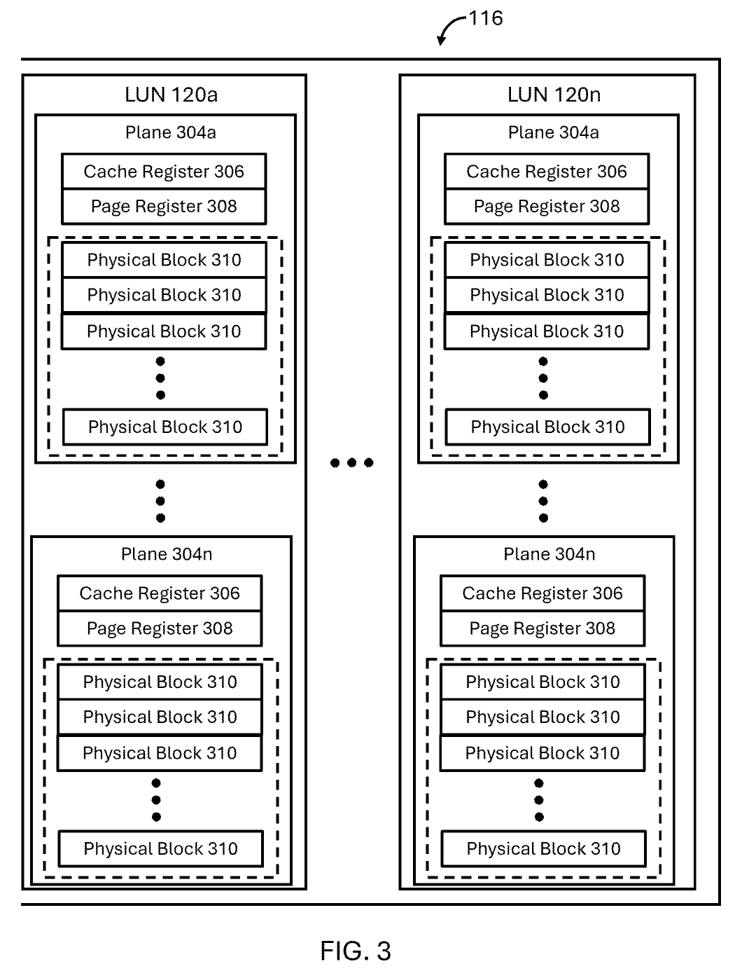

Turning to FIG. 3, the NVM media 116 may respectively include a plurality of dies. In various examples, the NVM media 116 may respectively include two (2), four (4), eight (8), sixteen (16), twenty four (24), thirty two (32), or more dies, without limitation. Each die may correspond to a logical unit (LUN). Each NVM 116 may include LUNs 120a, … 120n. Each LUN 120a, … 120n may include a plurality of planes 304a, … 304n. Each LUN 120a, … 120n may include, for example, four (4), six (6), eight (8), or more planes, without limitation.

Each plane may include a cache register 306, a page register 308, and a plurality of physical memory blocks 310. In various examples, the controller 106 may write incoming data to more than one NVM media 116 in parallel. The NVM media 116 may write incoming data to more than one LUN in parallel.

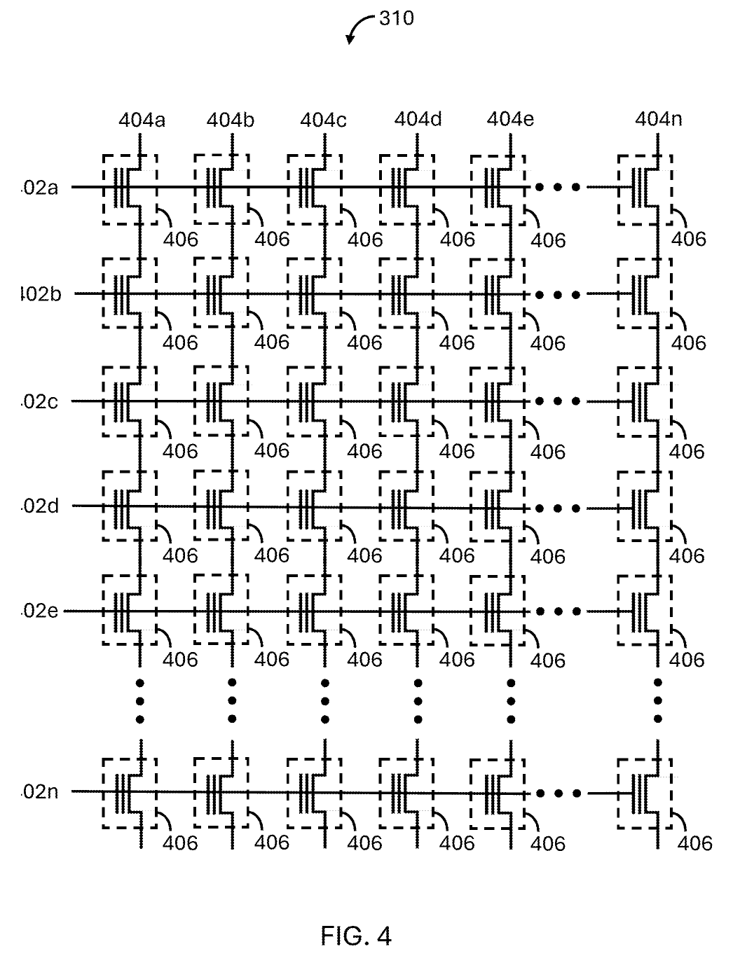

When data is written to or retrieved from the NVM media 116, the data may be temporarily stored in one of the cache register 306 and the page register 308. Each physical memory block 310 may include a set of pages (as described in connection with FIG. 4 below). The cache register 306 and the page register 308 may respectively have an equivalent data capacity of one page. Accordingly, data to be written to a first page may be temporarily stored in the cache register 306 while data to be written to another page may be temporarily stored in the page register 308. Data to be read from a first page may be retrieved and temporarily stored in the cache register 306 while data to be read from another page may be stored in the page register 308. Accordingly, the cache register 306 and page register 308 enable double buffering of data to reduce data programming and read times.

Turning to FIG. 4, each of the physical memory blocks 310 includes a plurality of wordlines (WLs) 402a, 402b, 402c, 402d, 402e, … 402n, a plurality of bit lines (BLs) 404a, 404b, 404c, 404d, 404e, … 404n, and a plurality of cells 406. In various examples, a page may be defined as a row of cells connected to the same WL (e.g., the cells 406 connected to the WL 402a are collectively referred to as a page). Each page may include a plurality of cells 406. Each cell 406 may include a transistor having a gate, a source, and a drain. Data bits may be written to the cells 406 on a page-by-page basis. Data may be erased from the plurality of cells 406 on a physical memory block basis.

Generally, each WL is an electronic signal that, according to its voltage level, selects a row (or page) of cells. (Each WL 402a, 402b, 402c, 402d, 402e, … 402n may be drawn as a horizontal line shown in FIG. 4.) Each WL may be connected to control gates of the cells in a respective row of cells. When a specific WL is activated (e.g., when a read voltage is applied), the cells connected to that WL are selected for reading or writing. In NAND flash memory, cells are organized into a series of strings, with each string being connected to one of a plurality of BLs, wherein each BL is an electronic signal that connects the drains of cells in a column of cells. (Each BL 404a, 404b, 404c, 404d, 404e, … 404n may be drawn as a vertical line shown in FIG. 4.) Each BL, according to its voltage level, may enable data transfer to and from the cells of a selected WL during read and write operations. During a read operation, the voltage on the BL reflects a state of the selected cells (or page). Accordingly, the voltage of the BL may be measured to determine the value of the data in the selected cells. In other words, WLs effectively address rows of cells where data is being programmed to or read from, while BLs are highways on which data travel to reach the desired cell(s).

In various examples, the cells 406 may include single-level cells (SLCs), multi-level cells (MLCs), triple-level cells (TLCs), quadruple-level cells (QLCs), and/or penta-level cells (PLCs), without limitation. Accordingly, the WLs 402a, 402b, 402c, 402d, 402e, … 402n may be SLC wordlines, MLC wordlines, QLC wordlines and/or PLC wordlines, without limitation. In an example, a TLC wordline may include a lower page, a middle page, and an upper page. The lower page, middle page, and upper page may correspond to a page including a row of TLCs. The TLC wordline may be activated to write data to each of the upper, middle, and lower pages. Accordingly, an SLC wordline may include one (1) page, an MLC wordline may include two pages (2), a TLC wordline may include three (3) pages, a QLC wordline may include four (4) pages, and a PLC wordline may include five (5) pages.

Returning to FIG. 3, in various examples, the physical blocks 310 may be organized into virtual blocks (VBs). A VB may include one physical block from each plane of each LUN of each NVM 116 of the memory device 114. Each VB may include a set of virtual wordlines (VWL). Each VWL may include a set of WLs (e.g., a VWL may include one (1) WL from each physical block of a VB). In various examples, the data processing and programming operations of this disclosure may be performed on a VB/VWL basis. Also or alternatively, the data processing and programming operations may be performed on a physical block/WL basis without departing from the spirit of the present disclosure.

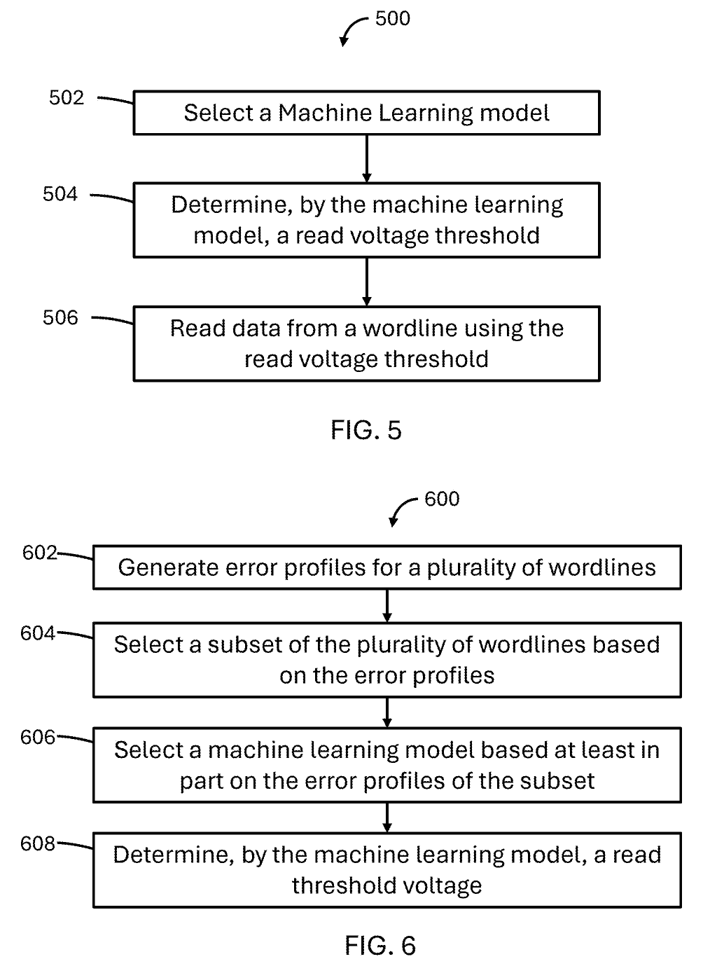

Returning to FIG. 1, in various examples, the ML component 112 may perform any and/or all operations described below with reference to FIGS. 5, 6, 7, and 8. In various examples, the ML component 112 may include a machine learning engine (MLE) including, for example, thirty-two (32) neurons, sixty-four (neurons), or more neurons, and two (2), four (4), or more hidden layers, without limitation. However, it is foreseen that the operations may be performed with other types of ML models without departing from the spirit of the present disclosure.

In various examples, a plurality of ML models may be stored on the local memory 110 and/or the ML component 112. The ML models may be trained during a manufacturing stage, such that the ML component 112 may utilize any of the ML models during operation. The ML models may be trained by another computing device, such as a computing system 200 of the manufacturer. Each of the ML models may include one or more of a regression model, a decision tree model, a support vector machine (SVM) model, a clustering model, an artificial neural network (ANN), a convolutional neural network (CNN), a recurrent neural network (RNN), a generative adversarial network (GAN), and/or the like, without limitation.

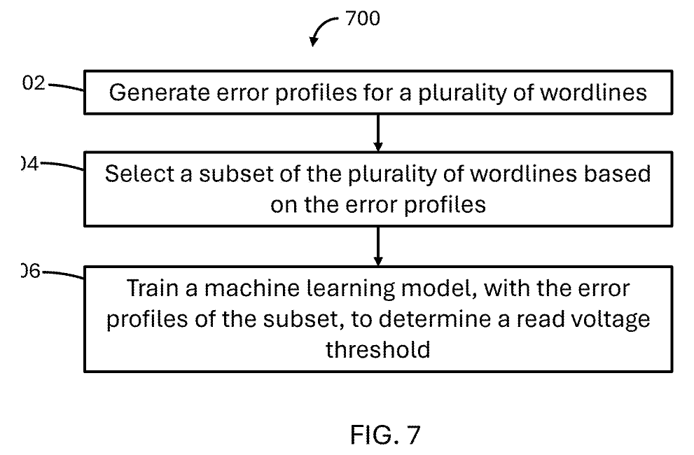

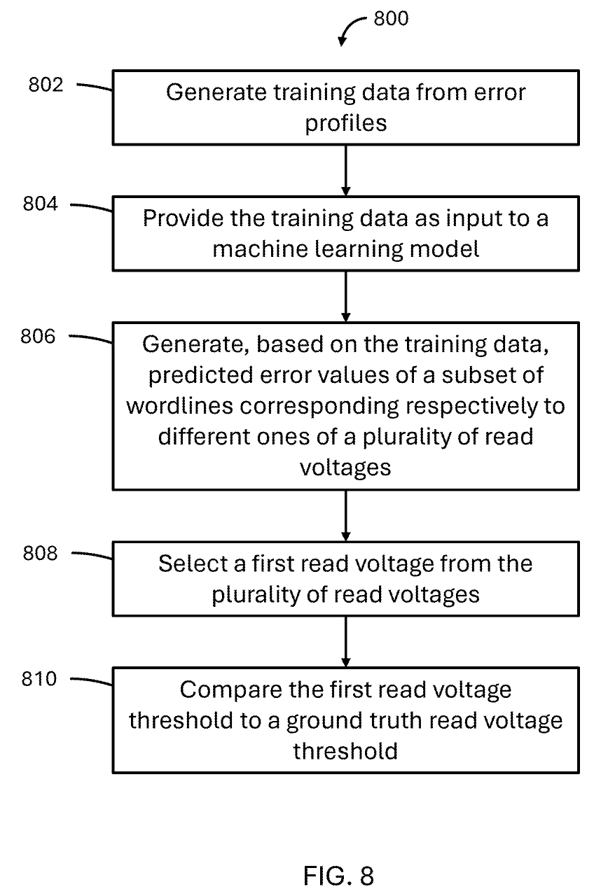

The ML models may be subject to supervised and/or unsupervised training. Training data may be generated based on error profiles of the WLs of the memory device 114 or of a similarly constructed memory device observed for generation of the training data. The training data may include labeled and/or unlabeled training data. The ML models may be trained on the training data to determine a read voltage threshold. Specific operations for training example ML models are described below with reference to FIGS. 7 and 8.

The ML component 112 may utilize a selected ML model to determine a read voltage threshold. In various examples, the selected ML model may perform a regression analysis of error values corresponding to a subset of WLs to determine an optimized read voltage threshold to be used for some or all of the WLs of the memory device 114 during read operations. Specific operations for operation of the ML models are described below with reference to FIGS. 5 and 6.

In various examples, instructions for executing the ML component 112 may be stored in the local memory 110. Some or all functions of the ML component 112 may be executed by the processor 108, the local controller(s) 118, other circuitry of the controller 106 and/or the memory device 114, and/or a combination thereof. Instructions for training the ML models may be stored in another computing device, such as a computing system 200 and/or a host system 102 of the manufacturer.

Through hardware, software, firmware, or various combinations thereof, any of the processing elements (e.g., the controller 106 and/or local controller(s) 118 of FIG. 1 and/or the processing element 202 of FIG. 2) may – alone or in combination with other processing elements – be configured to perform the operations of examples of the present disclosure. The examples described herein in connection with the attached drawing figures are intended to describe aspects of the disclosure in sufficient detail to enable those skilled in the art to practice the disclosure. Other examples can be utilized and changes can be made without departing from the scope of the present disclosure. The system may include additional, less, or alternate functionality and/or device(s), including those discussed elsewhere herein. The above and below detailed description is, therefore, not to be taken in a limiting sense. The scope of the present disclosure is defined only by the appended claims, along with the full scope of equivalents to which such claims are entitled, unless otherwise expressly stated and/or readily apparent to those skilled in the art from the description.

FIG. 5 illustrates an example method 500 for reading data using a read voltage determined by a trained ML model. The method 500 may be performed by a controller (e.g., the controller 106 and/or the ML component 112 of FIG. 1) of a data storage system (e.g., the data storage system 106 of FIG. 1). The data storage system may additionally include a memory device (e.g., the memory device 114 of FIG. 1). The memory device may include a WL (e.g., the WL 402a of FIG. 4). The data storage system may be connected to a host system (e.g., the host system 102 of FIG. 1).

The method 500 may be performed in connection with any one or more of the method 600 described in connection with FIG. 6, the method 700 described in connection with FIG. 7, and/or the method 800 described in connection with FIG. 8, within the scope of various examples.

At operation 502, a ML model may be selected based on error values of the WL. The ML model may be selected from a plurality of ML models. The ML models may be trained to determine a read voltage threshold based on error profiles of a subset of WLs of the memory device. For example, a first ML model may be trained based on error profiles resembling those of a first WL subset, such as where the first WL subset has corresponding error profiles which meet the same criteria. Accordingly, each WL of the first WL subset may have a similar error profile at the time of operation 502 (e.g., each WL of the subset produces around the same number of errors given the same conditions). A second ML model may be trained based on error profiles resembling those of a second WL subset, such as where the second WL subset has corresponding error profiles which meet the same (second) criteria, which differ from the first criteria. Accordingly, each WL of the second WL subset may have a similar error profile at the time of operation 502. Additional ML models of a plurality of ML models may also be included, along with corresponding error profile criteria. Error profile criteria may include a number of errors and/or types of errors produced by each WL, a number of P/E cycles associated with each WL, a data retention time associated with each WL, and/or an operating temperature of the memory device.

The error profiles for each WL subset used to train a respective ML model may, for example, be representative of error profiles of the WLs at various stages of the life cycle of the memory device. The example first and second criteria, representative of conditions expected or experienced at such life cycle stages, may be implemented outside each respective ML model, such as pursuant to one or more rules, or may be integral with the ML model, without departing from the spirit of the present disclosure.

In various examples, the WL may be one of a subset of WLs (e.g., the WLs 402, 402b, 402c of FIG. 4). The subset of WLs may be identified and grouped based on statistical information of the error profiles meeting one or more error profile criteria introduced above. The error profile criteria may include one or more of a number of read disturb errors, a number of P/E cycles, a temperature, and/or a data retention time, and the like, associated with a given WL. Accordingly, the subset of WLs may be associated with a similar number of read disturb errors, P/E cycles, temperature, and/or data retention time. The selected ML model may be trained (e.g., by the manufacturer) on error profiles of WLs having similar error profiles as the subset of WLs and/or producing a similar number of errors as the WL. More particularly, at operation 502 the ML model may be selected from among the plurality of ML models by matching the error profile of the WL and/or the error profile criteria of the WL, or, in each case, of the subset of WLs to which the WL belongs, to the ML model trained on the most similar error profile(s) and/or based on the most similar criteria.

At operation 504, the selected ML model may determine a read voltage threshold for the WL. The ML model may receive error values of the WL to be read (or of a subset of WLs to which that WL belongs) as input data. For example, one or more read operations may be performed on the WL (or subset of WLs) and a number of errors produced by the WL (or subset of WLs) in response to the one or more read operations may be input as the error values to the ML model. The read operations may be performed before selecting the ML model (e.g., as part of normal past operations of the memory device). In various examples, errors associated with the error values may be read disturb errors. The number of errors may correspond to read errors produced by the WL (or subset of WLs) using a current (e.g., default or previously determined) read voltage threshold.

In various examples, the input to the ML model may be based on or derived from such raw read error values. It is also foreseen that the error values may also or alternatively be used to select the ML model, for example according to the one or more external rules introduced above and rather than or in addition to being more directly input to the ML model, within the scope of the present disclosure.

The ML model may predict a number of errors produced by the WL (or subset of WLs) at each of a plurality of read voltage thresholds (e.g., a first number of predicted errors associated with an increased read voltage threshold, a second number of predicted errors associated with a decreased read voltage threshold, and so on). The ML model may select a read voltage threshold associated with a lowest number of predicted errors compared to predicted errors associated with others of the read voltage thresholds. Determining the read threshold using the ML model may reduce an amount of time used to optimize the read voltage threshold compared to conventional algorithms that require a large number of read operations.

At operation 506, data may be read from the WL (or subset of WLs) using the determined read voltage threshold. The determined read voltage threshold may be stored in memory (e.g., in a table) for future reference. The determined read voltage may be utilized to read data from some and/or all WLs of the memory device. For example, a reference voltage having a voltage value corresponding to the read voltage threshold may be utilized to read data from the cells of that WL.

In various examples, a new ML model may be selected when the error profiles for the subset of WLs are no longer similar to the error profiles used to train the selected ML model. For example, a new ML model may be selected when the subset of WLs produces a certain number of errors, undergoes a certain number of P/E cycles (e.g., every fifty (50), one-hundred (100), two hundred fifty (250), five hundred (500), or one thousand (1000) P/E cycles, without limitation), retains data for a certain amount of time, and/or when an operating temperature of the memory device increases or decreased by a certain amount. The new ML model may be selected based on error profile criteria of a new subset of WLs as described above. The new subset of WLs may include some or all WLs of the subset of WLs or may include a completely different subset of WLs.

FIG. 6 illustrates an example method 600 for determining a read voltage threshold by a trained machine learning model. The method 600 may be performed by a controller (e.g., the controller 106 and/or the ML component 112 of FIG. 1) of a data storage system (e.g., the data storage system 106 of FIG. 1). The data storage system may additionally include a memory device (e.g., the memory device 114 of FIG. 1). The data storage system may be connected to a host system (e.g., the host system 102 of FIG. 1).

In various examples, the method 600 may be performed in connection with any one or more of the method 500 described in connection with FIG. 5, the method 700 described in connection with FIG. 7, and/or the method 800 described in connection with FIG. 8, within the scope of the present examples.

At operation 602, error profiles may be generated for a plurality of WLs (e.g., the WLs 402a, 402b, 402c, 402d, 402e, … 402n of FIG. 4) or a plurality of physical blocks (e.g., the physical blocks 310 of FIG. 3) of the memory device. Each error profile may include a variety of characteristics associated with a respective one of of the WLs, such as error values (e.g., a number of error produced), error types (e.g., correctable, uncorrectable, read errors, write errors, and the like), a number of P/E cycles, a data retention time, one or more temperature values of the memory device, and the like, without limitation. The error profiles may be determined periodically and/or dynamically (e.g., in response to a read or write request, when a P/E threshold is reached or when a data retention time exceeds a certain amount).

At operation 604, a subset of the WLs may be selected based on the error profiles. The subset may be selected based on one or more of the characteristics included in the error profiles. For example, the subset of WLs may produce a similar number of errors having similar error types, have undergone a similar number of P/E cycles (e.g., within a threshold number of P/E cycles of each other), have retained data for a similar amount of time (e.g., within a threshold amount of time), and/or may have had data read and written at similar temperatures.

At operation 606, a ML model may be selected based at least in part on the error profiles of the subset. The selected ML model may have been trained (as discussed below with reference to FIGS. 7 and 8) on training data from error profiles of WLs having similar characteristics as the subset. The ML model may be selected from a plurality of ML models. Each of the plurality of ML models may have been trained on error profiles of different respective WL subsets and having differing characteristics.

At operation 608, the ML model may determine a read threshold voltage for the subset of WLs. In various examples, the determined read voltage may be utilized to read data from the subset of WLs. In various examples, the determined read voltage may be utilized to read data from the plurality of WLs more broadly. The read voltage threshold may be determined in the same manner as described with reference to operation 504 of the method 500 of FIG. 5, with redundant description thereof being avoided for brevity. A new ML model may be selected in the same manner as described with reference to operation 506 of FIG. 5, with redundant description thereof being avoided for brevity.

FIG. 7 illustrates an example method 700 for training a machine learning model to determine a read voltage threshold. The method 700 may be performed by a controller (e.g., the controller 106 and/or the ML component 112 of FIG. 1) of a data storage system (e.g., the data storage system 106 of FIG. 1). The data storage system may additionally include a memory device (e.g., the memory device 114 of FIG. 1). The data storage system may be connected to a host system (e.g., the host system 102 of FIG. 1). It should be noted that training may occur on and/or based on read operations performed on a different physical device (e.g., of a manufacturer) from the physical device on which the trained ML model is to be used operationally. In various examples, the physical devices are similarly constructed.

In various examples, the method 700 may be performed in connection with any one or more of the method 500 described in connection with FIG. 5, the method 600 described in connection with FIG. 6, and/or the method 800 described in connection with FIG. 8, within the scope of the present examples.

At operation 702, error profiles may be generated for a plurality of WLs (e.g., the WLs 402a, 402b, 402c, 402d, 402e, … 402n of FIG. 4) or a plurality of physical blocks (e.g., the physical blocks 310 of FIG. 3) of the memory device. The error profiles may be generated in the same manner as described with reference to operation 602 of the method 600 of FIG. 6, with redundant description thereof being avoided for brevity. In various examples, the error profiles may be generated from historical data of a plurality of wordlines of various memory devices (e.g., during or subsequent to a manufacturing process).

At operation 704, a subset of the WLs may be selected based on the error profiles. The subset may be selected in the same manner as described with reference to operation 604 of the method 600 of FIG. 6, with redundant description thereof being avoided for brevity.

At operation 706, a ML model may be trained with the error profiles of the subset to determine a read voltage threshold. Training data may be generated from the error profiles of the subset. The training data may be provided as input to the ML model. The ML model may be trained to determine read voltage thresholds based on the training data. In various examples, the ML model may be iteratively trained until an accuracy criteria is met. An example training process is described in more detail in connection with the description of the method 800 of FIG. 8.

In various examples, a plurality of ML models may be trained on error profiles of various subsets of WLs. Each ML model may be trained based on error profiles for a different WL subset. The error profiles for the different WL subsets may, for example, be representative of error profiles of the WLs at various stages of the life cycle of the memory device. For example, a first ML model may be trained based on error profiles of a first WL subset producing a first number of errors and having around 500 P/E cycles. A second ML model may be trained based on error profiles of a second WL subset producing a second number of errors and having around 1000 P/E cycles. Accordingly, various ML models may be trained to determine read voltage thresholds for different subsets of WLs having different characteristics.

FIG. 8 illustrates an example method 800 for training a machine learning model to determine a read voltage threshold. The method 800 may be performed by a controller (e.g., the controller 106 and/or the ML component 112 of FIG. 1) of a data storage system (e.g., the data storage system 106 of FIG. 1). The data storage system may additionally include a memory device (e.g., the memory device 114 of FIG. 1). The data storage system may be connected to a host system (e.g., the host system 102 of FIG. 1). It should be noted that training may occur on and/or based on read operations performed on a different physical device (e.g., of a manufacturer) from the physical device on which the trained ML model is to be used operationally. In various examples, the physical devices are similarly constructed.

In various examples, the method 800 may be performed in connection with any one or more of the method 500 described in connection with FIG. 5, the method 600 described in connection with FIG. 6, and/or the method 700 described in connection with FIG. 7 (e.g., as part of operation 706), within the scope of the present examples.

At operation 802, training data may be generated from error profiles of a plurality of WLs of the memory device. In some examples, the plurality of WLs may include each WL of the memory device. In other examples, the plurality of WLs may include one or more subsets of WLs of the memory device. In various examples, the training data may include labeled or unlabeled training data. The training data may include error profile vectors including some or all of the characteristics of the error profiles. In various examples, different training data may be generated for different subsets of WLs to train different ML models.

At operation 804, the training data may be provided as input to the ML model. In various examples implementing an ANN with or comprising the ML model, the training data may take the form of an input vector.

At operation 806, the ML model may predict error values for the plurality of WLs based on the training data. The predicted error values may include a first set of error values associated with a first read threshold voltage, a second set of predicted error values associated with a second read threshold voltage, and so on.

At operation 808, the ML model may select a first read voltage from the plurality of read voltage thresholds. The first read voltage may be associated with a lowest number of predicted error values compared to the remaining ones of the purity of read voltage thresholds.

At operation 810, the first read voltage may be compared to a ground truth read voltage threshold to determine an accuracy of the ML model. The accuracy may be compared to an accuracy criteria. If the accuracy does not meet the accuracy criteria, the ML model may be retrained (in the same manner described in connection with operations 802-808) to generate a retrained ML model. The retraining process may be performed iteratively until the ML model meets the accuracy criteria. Training may include either supervised or unsupervised training. The accuracy criteria and/or ground truth read voltage threshold may comprise a reward function for training the ML model (e.g., via backpropagation and reinforcement learning) without departing from the spirit of the present disclosure.

### FEATURE COMBINATIONS

According to various examples of the present disclosure, a data storage system may include a memory device including a WL, a memory including instructions stored thereon, and at least one processor. The memory may include instructions stored thereon that, when executed by the at least one processor, cause the at least one processor to: select a ML model based at least in part on error values for the WL; determine, by the ML model, a read voltage threshold; and read data from the WL using the read voltage threshold.

According to various examples of the present disclosure, a computer-implemented method may include: generating error profiles for a plurality of WLs; selecting a subset of the plurality of WLs based on the error profiles; selecting a ML model based at least in part on the error profiles of the subset; and determining, by the ML model, a read threshold voltage.

According to various examples of the present disclosure, a computer-implemented method may include: generating error profiles for a plurality of WLs; selecting a subset of the plurality of WLs based on the error profiles; and training a ML model, with the error profiles of the subset, to determine a read voltage threshold.

In combination with any of the previous examples, a determination of a read voltage threshold may include providing error values as input to a ML model.

In combination with any of the previous examples, a determination of a read voltage threshold may include: generating, based on error values, predicted error values of a WL for respective ones of a plurality of read voltage thresholds; and selecting the read voltage threshold from the plurality of read voltage thresholds. The read voltage threshold may be associated with a lower number of the predicted error values relative to others of the plurality of read voltage thresholds.

In combination with any of the previous examples, a selection of an ML model may be based at least in part on one or more of: a number of P/E cycles associated with a WL, one or more temperature values, or a data retention time associated with the WL.

In combination with any of the previous examples, error values may include a number of read disturb errors.

In combination with any of the previous examples, a memory device may include a plurality of WLs. A WL may be one of the plurality of WLs.

In combination with any of the previous examples, data may be read from a second WL of a plurality of WLs using a read voltage threshold.

In combination with any of the previous examples, error profiles of a subset may meet one or more error profile criteria.

In combination with any of the previous examples, one or more error profile criteria may include at least one of: a number of read disturb errors, a number of program/erase (P/E) cycles, a temperature, or a data retention time.

In combination with any of the previous examples, a determination of a read voltage threshold may include: generating, based at least in part on error profiles of a subset, predicted error values of the subset for respective ones of a plurality of read voltage thresholds; and selecting the read voltage threshold from the plurality of read voltage thresholds, the read voltage threshold being associated with a lower number of the predicted error values relative to others of the plurality of read voltage thresholds.

In combination with any of the previous examples, a selection of a ML model may be based at least in part on one or more of: a number of program/erase (P/E) cycles associated with a subset, one or more temperature values, or a data retention time associated with the subset.

In combination with any of the previous examples, a read voltage threshold may be a first read voltage threshold of a plurality of read voltage thresholds. Training of an ML model may include: generating training data from error profiles; providing the training data as input to the ML model; generating, based on the training data, predicted error values of a plurality of WLs corresponding respectively to different ones of the plurality of read voltage thresholds; selecting the first read voltage threshold from the plurality of read voltage thresholds, the first read voltage threshold being associated with a lower number of the predicted error values than others of the plurality of read voltage thresholds; and comparing the first read voltage threshold to a ground truth read voltage threshold.

In combination with any of the previous examples, an accuracy of an ML model may be determined based on a comparison of a first read voltage threshold and a ground truth read voltage threshold.

In combination with any of the previous examples, a determination may be made that an accuracy does not meet accuracy criteria. Based on the determination that the accuracy criteria are not met, an ML model may be retrained to generate a retrained ML model. A determination may be made that the accuracy of the retrained model meets the accuracy criteria.

### GENERAL CONSIDERATIONS

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

Certain embodiments are described herein as including logic or a number of routines, subroutines, applications, or instructions. These may constitute either software (e.g., code embodied on a machine-readable medium or in a transmission signal) or hardware. In hardware, the routines, etc., are tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as computer hardware that operates to perform certain operations as described herein.

In various embodiments, computer hardware, such as a processing element, may be implemented as special purpose or as general purpose. For example, the processing element may comprise dedicated circuitry or logic that is permanently configured, such as an application-specific integrated circuit (ASIC), or indefinitely configured, such as an FPGA, to perform certain operations. The processing element may also comprise programmable logic or circuitry (e.g., as encompassed within a general-purpose processor or other programmable processor) that is temporarily configured by software to perform certain operations. It will be appreciated that the decision to implement the processing element as special purpose, in dedicated and permanently configured circuitry, or as general purpose (e.g., configured by software) may be driven by cost and time considerations.

Accordingly, the term “processing element” or equivalents should be understood to encompass a tangible entity, be that an entity that is physically constructed, permanently configured (e.g., hardwired), or temporarily configured (e.g., programmed) to operate in a certain manner or to perform certain operations described herein. Considering embodiments in which the processing element is temporarily configured (e.g., programmed), each of the processing elements need not be configured or instantiated at any one instance in time. For example, where the processing element comprises a general-purpose processor configured using software, the general-purpose processor may be configured as respective different processing elements at different times. Software may accordingly configure the processing element to constitute a particular hardware configuration at one instance of time and to constitute a different hardware configuration at a different instance of time.

Computer hardware components, such as communication elements, memory elements, processing elements, and the like, may provide information to, and receive information from, other computer hardware components. Accordingly, the described computer hardware components may be regarded as being communicatively coupled. Where multiple of such computer hardware components exist contemporaneously, communications may be achieved through signal transmission (e.g., over appropriate circuits and buses) that connect the computer hardware components. In embodiments in which multiple computer hardware components are configured or instantiated at different times, communications between such computer hardware components may be achieved, for example, through the storage and retrieval of information in memory structures to which the multiple computer hardware components have access. For example, one computer hardware component may perform an operation and store the output of that operation in a memory device to which it is communicatively coupled. A further computer hardware component may then, at a later time, access the memory device to retrieve and process the stored output. Computer hardware components may also initiate communications with input or output devices, and may operate on a resource (e.g., a collection of information).

The various operations of example methods described herein may be performed, at least partially, by one or more processing elements that are temporarily configured (e.g., by software) or permanently configured to perform the relevant operations. Whether temporarily or permanently configured, such processing elements may constitute processing element-implemented modules that operate to perform one or more operations or functions. The modules referred to herein may, in some example embodiments, comprise processing element-implemented modules.

Similarly, the methods or routines described herein may be at least partially processing element-implemented. For example, at least some of the operations of a method may be performed by one or more processing elements or processing element-implemented hardware modules. The performance of certain of the operations may be distributed among the one or more processing elements, not only residing within a single machine, but deployed across a number of machines. In some example embodiments, the processing elements may be located in a single location (e.g., within a home environment, an office environment or as a server farm), while in other embodiments the processing elements may be distributed across a number of locations.

Unless specifically stated otherwise, discussions herein using words such as “processing,” “computing,” “calculating,” “determining,” “presenting,” “displaying,” or the like may refer to actions or processes of a machine (e.g., a computer with a processing element and other computer hardware components) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

Although the invention has been described with reference to the embodiments illustrated in the attached drawing figures, it is noted that equivalents may be employed and substitutions made herein without departing from the scope of the invention as recited in the claims.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. A data storage system comprising:
a memory device including a wordline (WL);
memory storing instructions thereon; and
at least one processor, wherein the instructions, when executed by the at least one processor, cause the at least one processor to:
select a machine learning (ML) model based at least in part on error values for the WL,
determine, by the ML model, a read voltage threshold,
read data from the WL using the read voltage threshold.

2. The data storage system of claim 1, the determination of the read voltage threshold including providing the error values as input to the ML model.

3. The data storage system of claim 2, the determination of the read voltage threshold including:
generating, based on the error values, predicted error values of the WL for respective ones of a plurality of read voltage thresholds; and
selecting the read voltage threshold from the plurality of read voltage thresholds, the read voltage threshold being associated with a lower number of the predicted error values relative to others of the plurality of read voltage thresholds.

4. The data storage system of claim 1, the selection of the ML model being based at least in part on one or more of: a number of program/erase (P/E) cycles associated with the WL, one or more temperature values, or a data retention time associated with the WL.

5. The data storage system of claim 1, the error values including a number of read disturb errors.

6. The data storage system of claim 1, the memory device including a plurality of WLs, the WL being one of the plurality of WLs.

7. The data storage system of claim 6, the instructions, when executed by the at least one processor, causing the at least one processor to:
read data from a second WL of the plurality of WLs using the read voltage threshold.

8. A computer-implemented method comprising:
generating error profiles for a plurality of wordlines (WLs);
selecting a subset of the plurality of WLs based on the error profiles;
selecting a machine learning (ML) model based at least in part on the error profiles of the subset; and
determining, by the ML model, a read threshold voltage.

9. The computer-implemented method of claim 8, the error profiles of the subset meeting one or more error profile criteria.

10. The computer-implemented method of claim 9, the one or more error profile criteria including at least one of: a number of read disturb errors, a number of program/erase (P/E) cycles, a temperature, or a data retention time.

11. The computer-implemented method of claim 8, the determination of the read voltage threshold including:
generating, based at least in part on the error profiles of the subset, predicted error values of the subset for respective ones of a plurality of read voltage thresholds; and
selecting the read voltage threshold from the plurality of read voltage thresholds, the read voltage threshold being associated with a lower number of the predicted error values relative to others of the plurality of read voltage thresholds.

12. The computer-implemented method of claim 8, the selection of the ML model being based at least in part on one or more of: a number of program/erase (P/E) cycles associated with the subset, one or more temperature values, or a data retention time associated with the subset.

13. The computer-implemented method of claim 8, comprising:
reading data from at least one WL of the plurality of WLs using the read voltage threshold.

14. A computer-implemented method comprising:
generating error profiles for a plurality of wordlines (WLs);
selecting a subset of the plurality of WLs based on the error profiles; and
training a machine learning (ML) model, with the error profiles of the subset, to determine a read voltage threshold.

15. The computer-implemented method of claim 14, the error profiles respectively including at least one of: a number of read disturb errors, a number of program/erase (P/E) cycles, a temperature, or a data retention time.

16. The computer-implemented method of claim 14, the read voltage threshold being a first read voltage threshold of a plurality of read voltage thresholds, the training of the ML model including:
generating training data from the error profiles;
providing the training data as input to the ML model;
generating, based on the training data, predicted error values of the plurality of WLs corresponding respectively to different ones of the plurality of read voltage thresholds;
selecting the first read voltage threshold from the plurality of read voltage thresholds, the first read voltage threshold being associated with a lower number of the predicted error values than others of the plurality of read voltage thresholds; and
comparing the first read voltage threshold to a ground truth read voltage threshold.

17. The computer-implemented method of claim 16, comprising:
based on the comparison of the first read voltage threshold and the ground truth read voltage threshold, determining an accuracy of the ML model.

18. The computer-implemented method of claim 17, comprising:
determining that the accuracy does not meet accuracy criteria;
based on the determination that the accuracy criteria are not met, retraining the ML model to generate a retrained ML model; and
determining that an accuracy of the retrained ML model meets the accuracy criteria.

19. The computer-implemented method of claim 14, the error profiles of the subset meeting one or more error profile criteria.

20. The computer-implemented method of claim 19, the one or more error profile criteria including at least one of: a number of read disturb errors, a number of program/erase (P/E) cycles, a temperature, or a data retention time.
